(19) United States
(12) Patent Application Publication
(10) Pub. No.: US 2026/0143766 A1
(43) Pub. Date: May 21, 2026

(54) SEMICONDUCTOR DEVICE

(71) Applicant: FUJI ELECTRIC CO., LTD., Kanagawa (JP)

(72) Inventor: Kenichi IGUCHI, Matsumoto-city (JP)

(21) Appl. No.: 19/334,918

(22) Filed: Sep. 21, 2025

(30) Foreign Application Priority Data
Nov. 18, 2024 (JP) 2024-200861

(51) Int. Cl. H10D 62/13; H10D 12/00; H10D 62/10; H10D 64/00

(52) U.S. Cl. CPC H10D 62/145; H10D 12/481; H10D 62/127; H10D 64/117

(57) ABSTRACT

There is provided a semiconductor device comprising: a drift region provided in a semiconductor substrate; a gate trench portion provided on a front surface of the semiconductor substrate; a base region provided above the drift region; an emitter region which is provided above the base region and has a doping concentration which is higher than the drift region; and a trench contact portion which is provided from the front surface of the semiconductor substrate to a position deeper than an upper end of the base region.

The contents of the following patent application (s) are incorporated herein by reference:

NO. 2024-200861 filed in JP on November 18, 2024.

### BACKGROUND

### 1. TECHNICAL FIELD

The present invention relates to a semiconductor device.

### 2. RELATED ART

Patent document 1 describes that “it is preferable to improve a characteristic in a semiconductor device such as an IGBT device.”

### RELATED ART DOCUMENTS

### Patent Documents

Patent Document 1: Japanese Patent Application Publication No. 2023-128635

Patent Document 2: Japanese Patent Application Publication No. 2009-135360

Patent Document 3: Japanese Patent Application Publication No. 2008-91491

Patent Document 4: Japanese Patent Application Publication No. H10-173170

Patent Document 5: Japanese Patent Application Publication No. H9-283755

### BRIEF DESCRIPTION OF THE DRAWINGS

FIG. 1 is a top view illustrating an example of a semiconductor device 100.

FIG. 2 is an example of an enlarged view of a region D in FIG. 1.

FIG. 3 illustrates an example of a cross section taken along a line a-a in FIG. 2.

FIG. 4 illustrates a relationship between a doping concentration distribution and an electron concentration distribution.

FIG. 5A illustrates an example of an ON operation of the semiconductor device 100.

FIG. 5B illustrates an example of an OFF operation of the semiconductor device 100.

FIG. 6A illustrates an example of an ON operation of a semiconductor device according to a comparative example.

FIG. 6B illustrates another example of an ON operation of a semiconductor device according to the comparative example.

FIG. 7 illustrates another example of the cross section taken along the line a-a in FIG. 2.

FIG. 8 illustrates another example of the cross section taken along the line a-a in FIG. 2.

FIG. 9 illustrates another example of the cross section taken along the line a-a in FIG. 2.

FIG. 10 illustrates another example of the cross section taken along the line a-a in FIG. 2.

FIG. 11 illustrates another example of the cross section taken along the line a-a in FIG. 2.

FIG. 12 is another example of the enlarged view of the region D in FIG. 1.

FIG. 13 illustrates an example of a cross section taken along a line a-a in FIG. 12.

FIG. 14 is another example of the enlarged view of the region D in FIG. 1.

FIG. 15A illustrates an example of a cross section taken along a line a-a in FIG. 14.

FIG. 15B illustrates another example of the cross section taken along the line a-a in FIG. 14.

FIG. 16 is another example of the enlarged view of the region D in FIG. 1.

FIG. 17 illustrates an example of a cross section taken along a line b-b in FIG. 16.

### DESCRIPTION OF EXEMPLARY EMBODIMENTS

The present invention will be described below by way of embodiments of the invention, but the embodiments below are not intended to limit the invention according to the claims. In addition, not all combinations of features described in the embodiments are necessarily essential to a solution of the invention.

In the present specification, in a direction parallel to a depth direction of a semiconductor substrate, one side is referred to as “upper” or “front”, and another side is referred to as “lower” or “back”. Among two main surfaces of a substrate, a layer, or another member, one surface is referred to as an upper surface or a front surface, and another surface is referred to as a lower surface or a back surface. An “upper”, “lower”, “front”, or “back” direction is not limited to a direction of gravity, or a direction in which a semiconductor device is implemented.

In the present specification, technical matters may be described using orthogonal coordinate axes of an X axis, a Y axis, and a Z axis. The orthogonal coordinate axes merely specify relative positions of components and are not limited to a particular direction. For example, the Z axis is not limited to indicate a height direction with respect to the ground. Note that a +Z axis direction and a -Z axis direction are directions opposite to each other. When a Z axis direction is described without its sign, it means a direction parallel to the +Z axis and the -Z axis.

In the present specification, orthogonal axes parallel to the front surface and the back surface of the semiconductor substrate are defined as the X axis and the Y axis. In addition, an axis perpendicular to the front surface and the back surface of the semiconductor substrate is defined as the Z axis. In the present specification, the direction of the Z axis may be referred to as the depth direction. In addition, in the present specification, a direction parallel to the front surface and the back surface of the semiconductor substrate, including an X axis and a Y axis, may be referred to as a horizontal direction.

A region extending from a center in the depth direction of the semiconductor substrate to the front surface of the semiconductor substrate may be referred to as a front surface side. Similarly, a region extending from the center in the depth direction of the semiconductor substrate to the back surface of the semiconductor substrate may be referred to as a back surface side.

In the present specification, when referred to as “same” or “equal”, it may include a case which includes an error due to a variation in manufacturing or the like. The error is, for example, within 10%.

In the present specification, a conductivity type of a doping region to which impurities have doped is described as a P type or an N type. In the present specification, the impurities may particularly mean either a donor of the N type or an acceptor of the P type, and may be described as a dopant. In the present specification, doping means introducing the donor or the acceptor into the semiconductor substrate and turning it into a semiconductor which exhibits a conductivity type of the N type, or a semiconductor which exhibits a conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect, in which a vacancy (V), oxygen (O), and hydrogen (H) in the semiconductor combine, functions as a donor which supplies electrons. In the present specification, the VOH defect may be referred to as a hydrogen donor.

In the present specification, a P+ type or an N+ type means that it has a doping concentration which is higher than that of the P type or the N type, and a P- type or an N- type means that it has a doping concentration which is lower than that of the P type or the N type. In the present specification, a unit system is the SI units unless otherwise noted. Although a length may be indicated in cm, various calculations may be performed after conversion to meters (m).

In the present specification, a chemical concentration refers to an atomic density of impurities measured regardless of an electrical activation state. The chemical concentration (the atomic density) can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in the thermal equilibrium state. In addition, in an N type region, since the donor concentration is sufficiently higher than the acceptor concentration, the carrier concentration of the region may be set as the donor concentration. Similarly, in a P type region, the carrier concentration of the region may be set as the acceptor concentration. In the present specification, the doping concentration of the N type region may be referred to as the donor concentration, and the doping concentration of the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atоms/cm³ or /cm³ is used to indicate a concentration per unit volume. This unit is used for a concentration of a donor or an acceptor in a semiconductor substrate, or a chemical concentration. A notation of atоms may be omitted.

The carrier concentration measured by the SRP method may be lower than the concentration of the donor or the acceptor. In a range where a current flows when spreading resistance is measured, carrier mobility of the semiconductor substrate may be lower than a value in a crystalline state. The reduction in the carrier mobility occurs when carriers are scattered due to disorder (disorder) of a crystal structure due to a lattice defect or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. Each concentration in the present specification may be a value at room temperature. As an example, a value at 300 K (Kelvin) (substantially 26.9 degrees C) may be used for a value at room temperature.

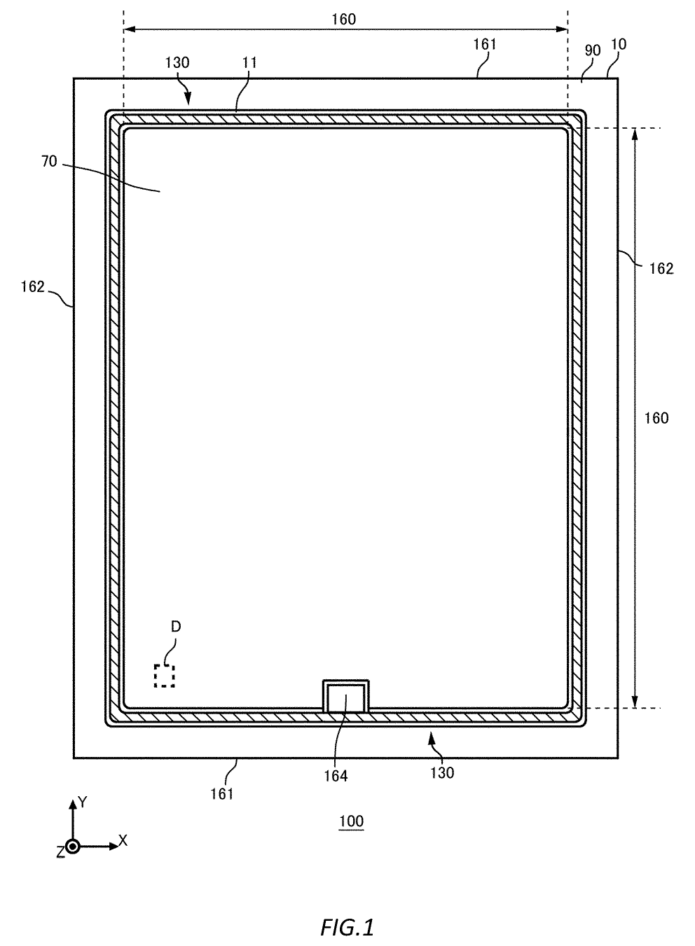

FIG. 1 is a top view illustrating an example of a semiconductor device 100. FIG. 1 illustrates a position of each member as being projected onto a front surface of a semiconductor substrate 10. FIG. 1 illustrates only some members of the semiconductor device 100, and an illustration of some members is omitted.

The semiconductor device 100 includes the semiconductor substrate 10. The semiconductor substrate 10 is a substrate formed of a semiconductor material. The semiconductor substrate may be a silicon substrate or a wide bandgap semiconductor substrate, but a material of the semiconductor substrate 10 is not limited thereto.

The semiconductor substrate 10 has a first end side 161 and a second end side 162 in a top view. In the present specification, when referred to simply as “in a top view”, it means viewing from the front surface side of the semiconductor substrate 10. The semiconductor substrate 10 of the present example includes two first end sides 161 opposite to each other in a top view. In addition, the semiconductor substrate 10 of the present example includes two second end sides 162 opposite to each other in a top view. In FIG. 1, the first end sides 161 are parallel to an X axis direction. The second end sides 162 are parallel to a Y axis direction. In addition, the Z axis is perpendicular to the front surface of the semiconductor substrate 10. In addition, the first end sides 161 are perpendicular to an extending direction or a longitudinal direction of a gate trench portion described below. The second end sides 162 are parallel to the extending direction or the longitudinal direction of the gate trench portion described below.

The semiconductor substrate 10 is provided with an active portion 160. The active portion 160 is a region where a main current flows in the depth direction between the front surface and the back surface of the semiconductor substrate 10 when the semiconductor device 100 is operated. An emitter electrode is provided above the active portion 160, but it is omitted in FIG. 1.

In the present example, the active portion 160 is provided with a transistor portion 70 including a transistor element such as an IGBT. In another example, the transistor portion 70 and a diode portion including a diode element such as a Free Wheel Diode, or FWD, may be arranged alternately along a predetermined arrangement direction in the front surface of the semiconductor substrate 10. Although one transistor portion 70 is provided in the present example, a plurality of transistor portions 70 may also be provided. A P+ type well region or a gate runner may be provided between the transistor portions 70.

The transistor portion 70 includes a P+ type collector region in a region in contact with the back surface of the semiconductor substrate 10. In addition, on the front surface side of the semiconductor substrate 10 in the transistor portion 70, surface MOS structures which include an N+ type emitter region, a P- type base region, an n- type drift region, a gate conductive portion, and a gate dielectric film are arranged at regular intervals.

The semiconductor device 100 may include one or more pads above the semiconductor substrate 10. The semiconductor device 100 of the present example includes a gate pad 164. The semiconductor device 100 may include a pad such as an anode pad, a cathode pad, and a current detection pad. Each pad is arranged in vicinity of the first end side 161. The vicinity of the first end side 161 refers to a region between the first end side 161 and the emitter electrode in a top view. When the semiconductor device 100 is implemented, each pad may be connected to an external circuit via a wiring line such as a wire.

A gate potential is applied to the gate pad 164. The gate pad 164 is electrically connected to a conductive portion of the gate trench portion in the active portion 160. The semiconductor device 100 includes a gate wiring line 130 which connects the gate pad 164 and the gate trench portion. In FIG. 1, the gate wiring line 130 is hatched with diagonal lines.

The gate wiring line 130 is arranged between the active portion 160 and the first end side 161 or the second end side 162 in a top view. The gate wiring line 130 of the present example surrounds the active portion 160 in a top view. A region surrounded by the gate wiring line 130 in a top view may be the active portion 160. In addition, the gate wiring line 130 is connected to the gate pad 164. The gate wiring line 130 is arranged above the semiconductor substrate 10. The gate wiring line 130 may be a metal wiring line including aluminum or the like. The gate wiring line 130 may be provided separately from the emitter electrode.

A P type outer circumferential well region 11 overlaps with the gate wiring line 130. That is, similar to the gate wiring line 130, the P type outer circumferential well region 11 surrounds the active portion 160 in a top view. The P type outer circumferential well region 11 also extends with a predetermined width in an area not overlapping with the gate wiring line 130. The P type outer circumferential well region 11 is a region of a second conductivity type. The P type outer circumferential well region 11 of the present example is of the P+ type.

The semiconductor device 100 may include a temperature sensing portion (not shown) which is a PN junction diode formed of polysilicon or the like, and a current detection portion (not shown) which simulates an operation of the transistor portion 70 provided in the active portion 160. The temperature sensing portion may be connected to the anode pad and the cathode pad via a wiring line. When the temperature sensing portion is provided, it is preferably provided at a center of the semiconductor substrate 10 along the X axis direction and the Y axis direction.

The semiconductor device 100 of the present example includes an edge termination structure portion 90 between the active portion 160 and the first end side 161 or the second end side 162 in a top view. The edge termination structure portion 90 of the present example is arranged between the outer circumferential gate wiring line 130 and the first end side 161 or the second end side 162. The edge termination structure portion 90 alleviates an electric field concentration on the front surface side of the semiconductor substrate 10. The edge termination structure portion 90 may include at least one of a guard ring, a field plate, or a RESURF which is annularly provided to surround the active portion 160.

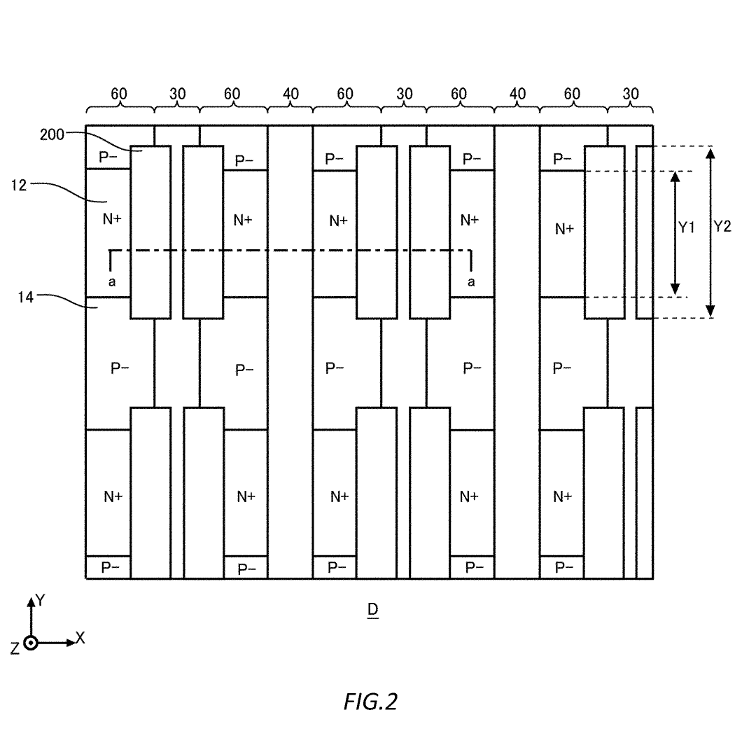

FIG. 2 is an example of an enlarged view of a region D in FIG. 1. The region D is a region which includes the transistor portion 70 in the active portion 160 shown in FIG. 1. FIG. 2 illustrates a structure of the front surface of the semiconductor substrate 10 in the region D. Although an interlayer dielectric film 38 and an emitter electrode 52 are provided above the front surface of the semiconductor substrate 10, they are omitted in FIG. 2. In the region D, the semiconductor device 100 includes one or more gate trench portions 40, one or more emitter regions 12, one or more base regions 14, and one or more trench contact portions 200. The semiconductor device 100 may further include one or more dummy trench portions 30. In the present specification, the gate trench portions 40 and the dummy trench portions 30 may each be referred to as a trench portion. In the present specification, when referred to simply as a trench portion, the trench portion may be either a gate trench portion 40 or a dummy trench portion 30.

The gate trench portion 40 has its longitudinal length in a first direction on the front surface of the semiconductor substrate 10. In the present example, the gate trench portion 40 extends in the Y axis direction, which is the first direction. The gate trench portion 40 is provided from the front surface of the semiconductor substrate 10 to inside of the semiconductor substrate 10. The gate conductive portion formed of a conductive material such as polysilicon is arranged inside the gate trench portion 40. The gate conductive portion is electrically connected to the gate wiring line 130 and applied with a predetermined gate voltage.

In a second direction intersecting with the first direction, a plurality of trench portions are arranged at predetermined intervals. The second direction of the present example is the X axis direction orthogonal to the first direction, or the Y axis direction. In the present example, the trench portion adjacent to the gate trench portion 40 in the Y axis direction may be the dummy trench portion 30. As illustrated in FIG. 2, the trench portion adjacent to the dummy trench portion 30 in the X axis direction may be the gate trench portion 40 or may be the dummy trench portion 30. In the X axis direction, one or more dummy trench portions 30 may be arranged between two gate trench portions 40. Note that, in another example, the dummy trench portions 30 may not be provided and the gate trench portions 40 may be arranged adjacent to each other in the X axis direction.

A region in the semiconductor substrate 10 which is sandwiched between two trench portions in the X axis direction is defined as a mesa portion 60. Each end of the mesa portion 60 in the X axis direction is a boundary portion with each trench portion. A depth position of a lower end of the mesa portion 60 is to be the same as a depth position of a lower end of at least one of the trench portions on both sides.

Each emitter region 12 is a region of a first conductivity type which is exposed at the front surface of the semiconductor substrate 10. As an example, the first conductivity type is the N type. The emitter region 12 is in contact with the gate trench portion 40. The emitter region 12 may be provided in each mesa portion 60 which is in contact with the gate trench portion 40. Each emitter region 12 may be in a shape of a strip which has its longitudinal length in the Y axis direction. A length of one emitter region 12 in the Y axis direction is defined as Y1. Since each emitter region 12 has its longitudinal length in the Y axis direction, a length of a channel formed below the emitter region 12 can be increased in the Y axis direction, which can improve a channel density. The emitter region 12 may be in contact with only one trench portion of the trench portions on both sides of the mesa portion 60 (in FIG. 2, the gate trench portion 40), and may not be in contact with another trench portion (in FIG. 2, the dummy trench portion 30).

As illustrated in FIG. 2, in one mesa portion 60, a plurality of emitter regions 12 may be arranged separately in the Y axis direction. A distance between two emitter regions 12 adjacent to each other in the Y axis direction may be shorter than the length Y1, or may be less than or equal to half, may be less than or equal to 1/4, or may be less than or equal to 1/10 of the length Y1. In another example, only one emitter region 12 may be continuously arranged in one mesa portion 60 in the Y axis direction. In this case, the length Y1 of the emitter region 12 may be half or more, or 3/4 or more, of a length of the mesa portion 60 in the Y axis direction.

Each base region 14 is a region of the second conductivity type which is provided above a drift region described below. As an example, the second conductivity type is the P type. The base region 14 of the present example is of P- type. As illustrated in FIG. 2, in one mesa portion 60, a plurality of base regions 14 may be arranged separately in the Y axis direction. Each base region 14 may be in a shape of a strip which has its longitudinal length in the Y axis direction. The base region 14 may also be provided below the emitter region 12.

Each trench contact portion 200 is provided from the front surface of the semiconductor substrate 10 to a position deeper than an upper end of the base region 14. The trench contact portion 200 may be provided above the dummy trench portion 30.

As illustrated in FIG. 2, a plurality of trench contact portions 200 may be arranged separately in the Y axis direction. Each trench contact portion 200 may be in a shape of a strip which has its longitudinal length in the Y axis direction. When a length of one trench contact portion 200 in the Y axis direction is defined as Y2, the length Y2 may be greater than the length Y1.

The trench contact portion 200 may be provided for each of the emitter regions 12 arranged separately in the Y axis direction. In another example, one trench contact portion 200 may be provided for two or more emitter regions 12 arranged separately in the Y axis direction. In addition, only one trench contact portion 200 may be arranged continuously for the plurality of emitter regions 12 provided in one mesa portion 60.

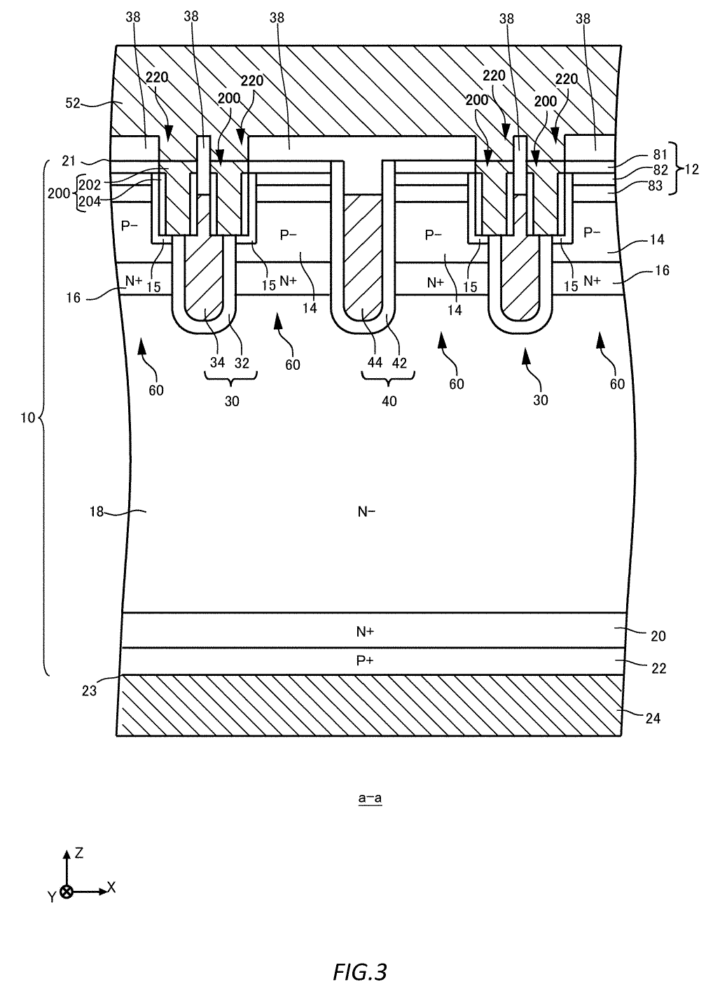

FIG. 3 illustrates an example of a cross section taken along a line a-a in FIG. 2. A cross section a-a is an XZ cross section passing through the emitter regions 12. The semiconductor device 100 of the present example includes the semiconductor substrate 10, the interlayer dielectric film 38, the emitter electrode 52, and a collector electrode 24 in the cross section.

The emitter electrode 52 is provided above the front surface 21 of the semiconductor substrate 10. A part of the front surface 21 of the semiconductor substrate 10 is covered with the interlayer dielectric film 38, and the emitter electrode 52 may be provided above the interlayer dielectric film 38.

The emitter electrode 52 is formed of a material including a metal. For example, at least a partial region of the emitter electrode 52 is formed of aluminum or an aluminum-silicon alloy, for example, a metal alloy such as AlSi, AlSiCu, or the like. The emitter electrode 52 may have a barrier metal formed of titanium, titanium nitride, or the like below the region formed of aluminum or the like. The emitter electrode 52 may include a metal plug formed of tungsten or the like below the region formed of aluminum or the like.

The collector electrode 24 is provided on the back surface 23 of the semiconductor substrate 10. Similar to the emitter electrode 52, the collector electrode 24 is formed of a metal material such as aluminum. In the present specification, a direction connecting the emitter electrode 52 and the collector electrode 24 (the Z axis direction) is referred to as the depth direction.

The interlayer dielectric film 38 is provided on the front surface 21 of the semiconductor substrate 10. The interlayer dielectric film 38 is a film including at least one layer of a dielectric film such as silicate glass to which impurities such as boron or phosphorus are added, a thermal oxide film, or another dielectric film. The interlayer dielectric film 38 may cover each trench portion.

The interlayer dielectric film 38 of the present example includes a plurality of contact holes 220. The contact holes 220 are provided between the emitter electrode 52 and the front surface 21 of the semiconductor substrate 10. Each contact hole 220 is filled with the emitter electrode 52.

Each mesa portion 60 is provided with the P- type base region 14. The base region 14 is in contact with the gate trench portion 40. The base region 14 may be in contact with each trench portion on both sides of the mesa portion 60. At least part of the base region 14 is provided below the emitter region 12. The base region 14 may be in contact with the emitter region 12. When a predetermined ON voltage is applied to the gate trench portion 40, a surface layer of the base region 14 in contact with the gate trench portion 40 is inverted to the N type region to form a channel. The channel electrically connects the emitter region 12 and a drift region 18.

The drift region 18 is a region of the first conductivity type which is provided in the semiconductor substrate 10. As an example, the drift region 18 is of an n- type. The emitter region 12 has a doping concentration which is higher than the drift region 18. The drift region 18 is provided below the base region 14. An N+ type accumulation region 16 may be provided between the drift region 18 and the base region 14, which has a higher doping concentration than the drift region 18. Providing the accumulation region 16 can produce an electron injection enhancement effect to decrease the ON voltage of the semiconductor device 100.

A P+ type collector region 22 is provided between the drift region 18 and the back surface 23 of the semiconductor substrate 10. A doping concentration of the collector region 22 is higher than that of the base region 14. The collector region 22 may include an acceptor which is the same as or different from an acceptor of the base region 14. The acceptor of the collector region 22 is, for example, boron. An element serving as the acceptor is not limited to the example described above. The collector region 22 is exposed at the back surface 23 of the semiconductor substrate 10 and connected to the collector electrode 24. The collector electrode 24 may be in contact with the entire back surface 23 of the semiconductor substrate 10.

An N+ type buffer region 20 may be provided between the drift region 18 and the collector region 22. A doping concentration of the buffer region 20 is higher than that of the drift region 18. The buffer region 20 may have one or more concentration peaks with a doping concentration higher than that of the drift region 18. A doping concentration at a concentration peak refers to a doping concentration at an apex of the concentration peak. In addition, as the doping concentration of the drift region 18, an average value of doping concentrations in a region where a doping concentration distribution is substantially flat may be used.

The buffer region 20 may be formed by ion implantation of the dopant of the N type such as hydrogen (proton) or phosphorus. The buffer region 20 of the present example is formed by the ion implantation of hydrogen. The buffer region 20 may function as a field stopper layer which prevents a depletion layer expanding from a lower end of the base region 14 from reaching the collector region 22.

The one or more gate trench portions 40 are provided on the front surface 21 of the semiconductor substrate 10. In the present example, a plurality of gate trench portions 40 are provided on the front surface 21 of the semiconductor substrate 10. In the present example, each gate trench portion 40 penetrates the base region 14 and reaches the drift region 18 from the front surface 21 of the semiconductor substrate 10. A structure in which the trench portions penetrate the doping region is not limited to a structure which is manufactured by forming the doping region first and then forming the trench portions. The structure in which the trench portions penetrate the doping region includes a structure which is manufactured by forming the trench portions first and then forming the doping region between the trench portions.

Each gate trench portion 40 includes a gate trench in a grooved shape provided on the front surface 21 of the semiconductor substrate 10, a gate dielectric film 42, and a gate conductive portion 44. The gate conductive portion 44 is formed of polysilicon, which is a conductive material. The gate dielectric film 42 covers an inner wall of the gate trench. The gate dielectric film 42 may be formed by oxidizing or nitriding a semiconductor on the inner wall of the gate trench. The gate conductive portion 44 is provided inside the gate dielectric film 42 in the gate trench. That is, the gate dielectric film 42 insulates the gate conductive portion 44 from the semiconductor substrate 10.

The gate conductive portion 44 in the gate trench portion 40 may be longer than the base region 14 in the depth direction. The gate trench portion 40 in the cross section is covered with the interlayer dielectric film 38 on the front surface 21 of the semiconductor substrate 10. The gate conductive portion 44 may be electrically connected to the gate wiring line 130 in a position which is not on the cross section illustrated in FIG. 3.

The dummy trench portion 30 has a similar structure to that of the gate trench portion 40. The dummy trench portion 30 of the present example has a dummy trench in a grooved shape, a dummy dielectric film 32, and a dummy conductive portion 34. A structure of the dummy trench, the dummy dielectric film 32, and the dummy conductive portion 34 may be similar to that of the gate trench, the gate dielectric film 42, and the gate conductive portion 44, respectively. The dummy trench portion 30 in the cross section is covered with the interlayer dielectric film 38 on the front surface 21 of the semiconductor substrate 10. The dummy conductive portion 34 may be electrically connected to the emitter electrode 52 in a position which is not on the cross section illustrated in FIG. 3.

The semiconductor device 100 of the present example includes the trench contact portion 200 below the contact hole 220. The trench contact portion 200 is a recessed portion formed from the front surface 21 of the semiconductor substrate 10 to the inside of the semiconductor substrate 10. The trench contact portion 200 is provided from the front surface of the semiconductor substrate 10 to a position deeper than the upper end of the base region 14.

The trench contact portion 200 includes a trench contact conductive portion 202 and a trench contact dielectric film 204. The trench contact conductive portion 202 is comprised of a material which is the same as, for example, the emitter electrode 52. The trench contact conductive portion 202 may include tungsten. The trench contact conductive portion 202 is in contact with the semiconductor substrate 10 on side surfaces and a bottom surface of the trench contact portion 200. The trench contact conductive portion 202 is connected to the emitter electrode 52 via the contact hole 220.

The trench contact dielectric film 204 is provided at least partially on the side surfaces of the trench contact portion 200. As an example, the trench contact dielectric film 204 is an oxide film. The trench contact dielectric film 204 may be in contact with a lower end of the trench contact portion 200. The trench contact dielectric film 204 may be provided on a side surface of the side surfaces of the trench contact portion 200 which faces the gate trench portion 40. The trench contact dielectric film 204 of the present example is provided on all side surfaces of the trench contact portion 200.

The trench contact portion 200 may be provided above the dummy trench portion 30. The trench contact portion 200 may include a plurality of trench contact portions 200 provided above the dummy trench portion 30. In the present example, two trench contact portions 200 are provided above one dummy trench portion 30. In another example, one trench contact portion 200 with a larger width than the dummy trench portion 30 in the X axis direction may be provided above one dummy trench portion 30. In such a structure, the trench contact portion 200 can be easily provided, even when the mesa portion 60 between the trench portions is miniaturized.

The bottom surface of the trench contact portion 200 of the present example is in contact with the dummy trench portion 30. The trench contact conductive portion 202 may be in contact with the dummy conductive portion 34. Thus, an emitter potential can be applied to the dummy conductive portion 34. Note that the dummy conductive portion 34 may be electrically connected to the emitter electrode 52 in a position which is not on the cross section illustrated in FIG. 3.

A contact region 15 is a region of the second conductivity type provided above the drift region 18 and having a doping concentration which is higher than the base region 14. As an example, the contact region 15 is of the P+ type. The contact region 15 may be in contact with the bottom surface of the trench contact portion 200. The contact region 15 may be in contact with the trench contact conductive portion 202 on the bottom surface of the trench contact portion 200. Thus, a hole current flowing toward the front surface 21 side of the semiconductor substrate 10 can be pulled out, thereby suppressing latch-up.

Although the side surfaces of the trench contact portion 200 is illustrated as being perpendicular to the front surface 21 of the semiconductor substrate 10 in FIG. 3, they may be tilted. In addition, although the bottom surface of the trench contact portion 200 is illustrated in a flat shape, it may have a shape which is bent downward. The side surfaces and the bottom surface of the trench contact portion 200 are distinguished from each other just for convenience. Portions in which outer surfaces of the trench contact portion 200 extend from the front surface 21 of the semiconductor substrate 10 in the depth direction may be referred to as side surfaces, and a portion which extends in a different direction from the side surfaces and connects the side surfaces with each other may be referred to as a bottom surface.

The emitter region 12 includes a first emitter portion 81, a second emitter portion 82, and a third emitter portion 83. The first emitter portion 81 is in contact with the front surface 21 of the semiconductor substrate 10. As an example, the first emitter portion 81 is of the N+ type. The first emitter portion 81 of the present example is in contact with a side surface of the gate trench portion 40. The first emitter portion 81 of the present example extends from the gate trench portion 40 to the trench contact portion 200 provided above the dummy trench portion 30 in the X axis direction.

The second emitter portion 82 is provided below the first emitter portion 81. The second emitter portion 82 may be in contact with the first emitter portion 81. The second emitter portion 82 is an N type region having a doping concentration which is lower than the first emitter portion 81. The second emitter portion 82 of the present example is in contact with the side surface of the gate trench portion 40. The second emitter portion 82 of the present example is not in contact with the trench contact conductive portion 202.

The second emitter portion 82 of the present example has a doping concentration which is lower than the first emitter portion 81. This makes a resistance value of the second emitter portion 82 higher than that of the first emitter portion 81. In addition, a current flowing between the first emitter portion 81 and the base region 14 passes through the second emitter portion 82. Thus, the second emitter portion 82 of the present example can function as a resistance portion and suppress a saturation current flowing through the MOS structure. In addition, by providing the emitter region 12 having its longitudinal length in the Y axis direction, a total emitter width in the Y axis direction becomes greater so that the ON voltage is decreased. In this manner, by providing the second emitter portion 82 which functions as a resistance portion, both a low saturation current and a low ON voltage can be achieved.

The third emitter portion 83 is provided below the second emitter portion 82. The third emitter portion 83 may be in contact with the second emitter portion 82. The third emitter portion 83 is an N+ type region having a doping concentration which is higher than the second emitter portion 82. The third emitter portion 83 may have a lower doping concentration than the first emitter portion 81. The third emitter portion 83 of the present example is in contact with the side surface of the gate trench portion 40. The third emitter portion 83 of the present example is not in contact with the trench contact conductive portion 202.

Since the third emitter portion 83 of the present example is not in contact with the trench contact conductive portion 202, electrons flowing from the emitter electrode 52 to the drift region 18 pass through the second emitter portion 82 via the trench contact conductive portion 202 and the first emitter portion 81. Thus, the second emitter portion 82 of the present example can function as a resistance portion and suppress the saturation current flowing through the MOS structure.

The trench contact dielectric film 204 is provided between the trench contact conductive portion 202 and the third emitter portion 83. Thus, the third emitter portion 83 is not in contact with the trench contact conductive portion 202, and the electrons flowing from the emitter electrode 52 to the drift region 18 pass through the second emitter portion 82 via the trench contact conductive portion 202 and the first emitter portion 81. Thus, the second emitter portion 82 of the present example can function as a resistance portion and suppress the saturation current flowing through the MOS structure. Note that a structure in which the trench contact dielectric film 204 is provided between the trench contact conductive portion 202 and the third emitter portion 83 includes a structure which includes a member other than the trench contact dielectric film 204 between the trench contact conductive portion 202 and the third emitter portion 83. In the present example, the trench contact dielectric film 204 and the contact region 15 are provided between the trench contact conductive portion 202 and the third emitter portion 83.

The contact region 15 may be in contact with the bottom surface and a side surface of the trench contact portion 200. The contact region 15 may be provided between the trench contact conductive portion 202 and the third emitter portion 83. Thus, the third emitter portion 83 is not in contact with the trench contact conductive portion 202, and the electrons flowing from the emitter electrode 52 to the drift region 18 pass through the second emitter portion 82 via the trench contact conductive portion 202 and the first emitter portion 81. Thus, the second emitter portion 82 of the present example can function as a resistance portion and suppress the saturation current flowing through the MOS structure.

The first emitter portion 81 may be in contact with the trench contact conductive portion 202. The third emitter portion 83 may be spaced apart from the trench contact conductive portion 202. Thus, the electrons flowing from the emitter electrode 52 to the drift region 18 pass through the second emitter portion 82 via the trench contact conductive portion 202 and the first emitter portion 81. Thus, the second emitter portion 82 of the present example can function as a resistance portion and suppress the saturation current flowing through the MOS structure.

The trench contact dielectric film 204 may be provided between the trench contact conductive portion 202 and the third emitter portion 83, and between the trench contact conductive portion 202 and the second emitter portion 82. Thus, the second emitter portion 82 and the third emitter portion 83 is not in contact with the trench contact conductive portion 202, and the electrons flowing from the emitter electrode 52 to the drift region 18 pass through the second emitter portion 82 via the trench contact conductive portion 202 and the first emitter portion 81. Thus, the second emitter portion 82 of the present example can function as a resistance portion and suppress the saturation current flowing through the MOS structure. Note that a structure in which the trench contact dielectric film 204 is provided between the trench contact conductive portion 202 and the second emitter portion 82 includes a structure which includes a member other than the trench contact dielectric film 204 between the trench contact conductive portion 202 and the second emitter portion 82. In the present example, the trench contact dielectric film 204 and the contact region 15 are provided between the trench contact conductive portion 202 and the second emitter portion 82.

The contact region 15 may be in contact with the bottom surface and the side surface of the trench contact portion 200. The contact region 15 may be provided between the trench contact conductive portion 202 and the second emitter portion 82.

The first emitter portion 81 may be in contact with the trench contact conductive portion 202. The second emitter portion 82 and the third emitter portion 83 may be spaced apart from the trench contact conductive portion 202. Thus, the electrons flowing from the emitter electrode 52 to the drift region 18 pass through the second emitter portion 82 via the trench contact conductive portion 202 and the first emitter portion 81. Thus, the second emitter portion 82 of the present example can function as a resistance portion and suppress the saturation current flowing through the MOS structure.

Although the trench contact dielectric film 204 of the present example is provided to an upper end of the second emitter portion 82 between the trench contact conductive portion 202 and the second emitter portion 82 so that the second emitter portion 82 is spaced apart from the trench contact conductive portion 202, the trench contact dielectric film 204 may terminate at an intermediate position of the second emitter portion 82 and the second emitter portion 82 may be partially in contact with the trench contact conductive portion 202. Since the resistance value of the second emitter portion 82 is higher than that of the first emitter portion 81, when the trench contact conductive portion 202 is in contact with the first emitter portion 81 and the second emitter portion 82, the electrons tend to flow through the first emitter portion 81 having lower resistance. Accordingly, the electrons flowing from the emitter electrode 52 to the drift region 18 pass through the second emitter portion 82 via the trench contact conductive portion 202 and the first emitter portion 81. Note that some electrons may pass through the second emitter portion 82 directly from the trench contact conductive portion 202.

In the depth direction of the semiconductor substrate 10, an upper end of the gate conductive portion 44 of the gate trench portion 40 is arranged to face the third emitter portion 83. The upper end of the gate conductive portion 44 may refer to an upper end on its side surface which faces the mesa portion 60. The phrase “the upper end of the gate conductive portion 44 faces the third emitter portion 83” means that in the Z axis direction, the upper end of the gate conductive portion 44 is arranged between an upper end position and a lower end position of the third emitter portion 83. An upper end and a lower end of the third emitter portion 83 may refer to an upper end and a lower end in a portion thereof which is in contact with the side surface of the gate trench portion 40.

When the ON voltage is applied to the gate conductive portion 44, electrons are attracted to a region in the mesa portion 60 which is a boundary portion with the trench portion and faces the gate conductive portion 44. When the second emitter portion 82 is arranged to face the gate conductive portion 44, the electrons are also attracted to a boundary portion in the second emitter portion 82. Since the second emitter portion 82 has a lower doping concentration, the attracted electrons may cause a variation in a resistance value in the boundary portion. In contrast, when the third emitter portion 83 is arranged to face the upper end of the gate conductive portion 44, the variation in the resistance value in the boundary portion of the second emitter portion 82 can be suppressed. In addition, since the third emitter portion 83 has a higher doping concentration, even when the electrons are attracted to a boundary portion in the third emitter portion 83, a variation in a resistance value in the boundary portion is very small.

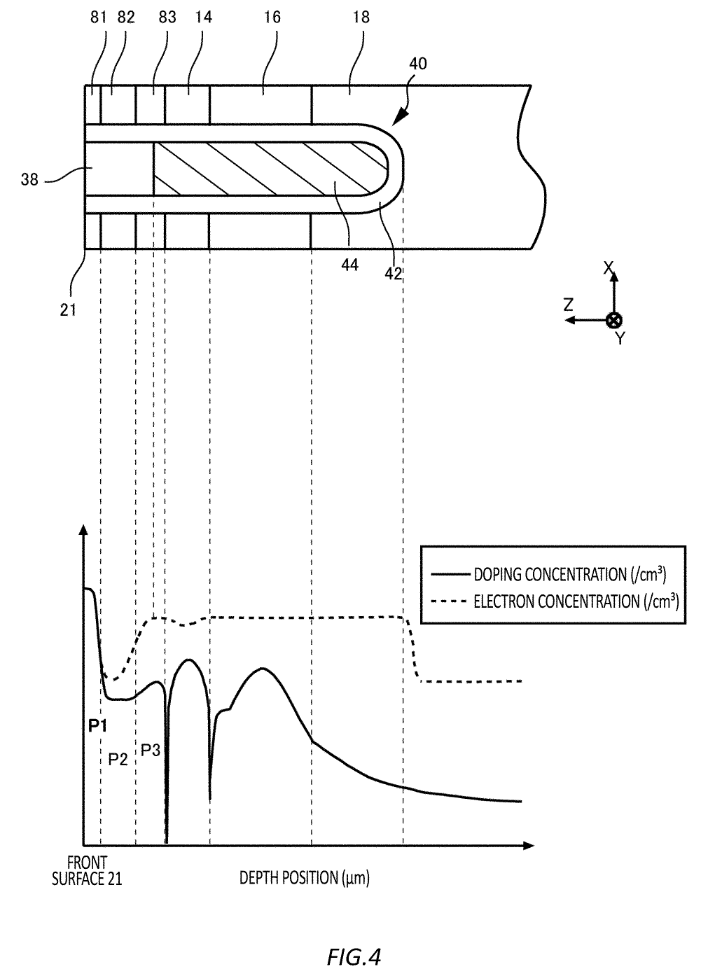

FIG. 4 illustrates a relationship between a doping concentration distribution and an electron concentration distribution. A horizontal axis of a graph indicates a position in the depth position, or -Z axis direction, from the front surface 21 of the semiconductor substrate 10. A plot by a solid line indicates the doping concentration distribution in the semiconductor substrate 10, and a plot by a dashed line indicates the electron concentration distribution when the saturation current is flowing. For reference, an XZ cross section around the gate trench portion 40 is illustrated next to the graph.

First, the doping concentration distribution will be described. The doping concentration distribution illustrated in FIG. 4 includes a portion P1 which corresponds to the first emitter portion 81, a portion P2 which corresponds to the second emitter portion 82, and a portion P3 which corresponds to the third emitter portion 83. The doping concentration distribution illustrated in FIG. 4 further includes portions each of which corresponds to the base region 14, the accumulation region 16, and the drift region 18, following P3.

The doping concentration distribution P1 of the first emitter portion 81 and the doping concentration distribution P3 of the third emitter portion 83 each have an upwardly-convex-shaped profile and include a peak portion. The peak portion is a portion in which the doping concentration exhibits a local maximum value. A peak portion of P3 may be lower than that of P1. That is, a doping concentration of the third emitter portion 83 may be lower than a maximum doping concentration of the first emitter portion 81.

The doping concentration distribution P2 of the second emitter portion 82 is a portion between P1 and P3. P2 may include a valley portion. The valley portion is a portion in which the doping concentration exhibits a local minimum value. P2 has a positive slope from the valley portion to the peak portion of P3. P2 may include a flat portion which partially extends between the valley portion and the peak portion of P3. The flat portion is a portion in which the doping concentration is not changed substantially. P2 may include a peak portion which is lower than that of P3, between the valley portion and the peak portion of P3.

Then, the electron concentration distribution will be described. When the ON voltage is applied to the gate trench portion 40, electrons are induced at a silicon interface which faces the gate conductive portion 44. An electron concentration when the saturation current is flowing is generally constant in the depth position of the gate conductive portion 44. The electron concentration rapidly decreases from the upper end of the gate conductive portion 44 to upward and exhibits a local minimum value in the second emitter portion 82.

As described with respect to FIG. 3, the upper end of the gate conductive portion 44 of the gate trench portion 40 is arranged to face the third emitter portion 83. That is, the depth position of the upper end of the gate conductive portion 44 may be within a depth range over which the third emitter portion 83 is provided. This can suppress the variation in the resistance value in the boundary portion of the second emitter portion 82. For example, the upper end of the gate conductive portion 44 is provided within a range of a full width at half maximum of the peak of the doping concentration distribution P3 of the third emitter portion 83.

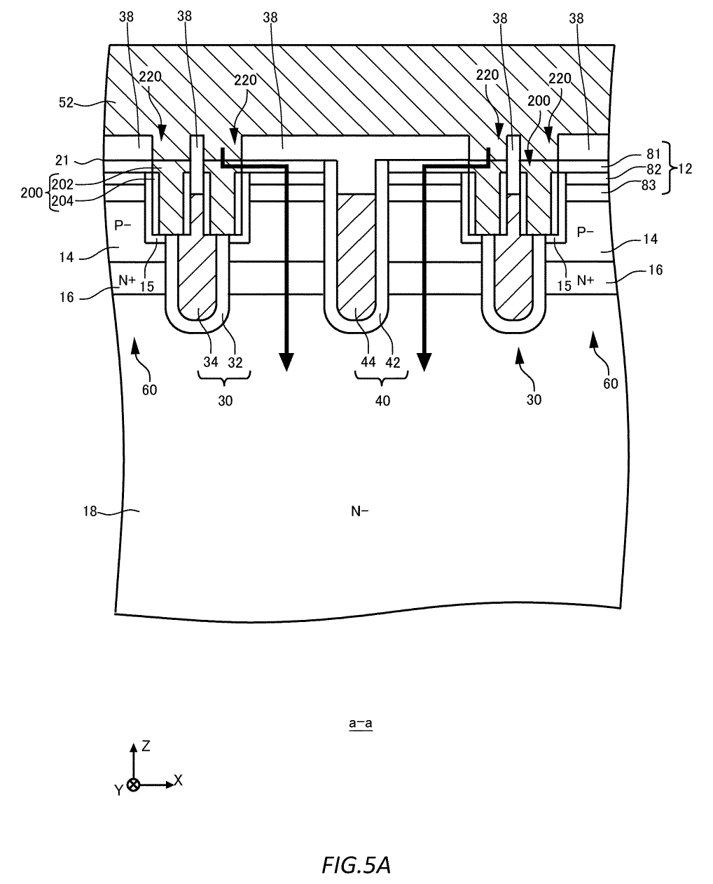

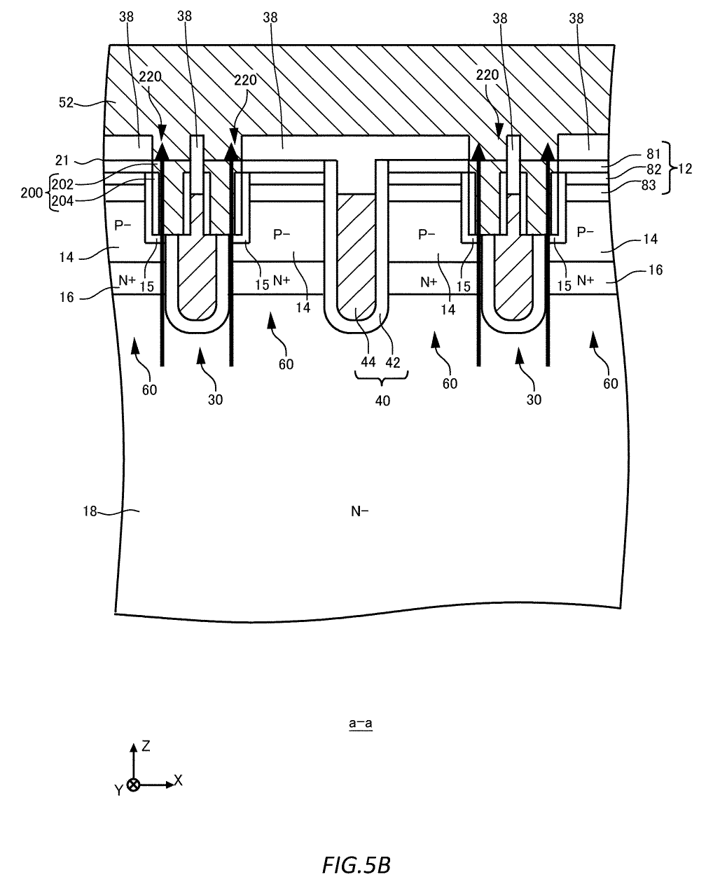

FIG. 5A illustrates an example of an ON operation of the semiconductor device 100. A bold arrow indicates a flow of electrons. The electrons are not injected from a part of the side surface of the trench contact portion 200, in which the trench contact dielectric film 204 is provided. In addition, at the bottom surface of the trench contact portion 200, since a portion in which the trench contact conductive portion 202 and the contact region 15 are in contact with each other is reverse-biased, the electrons are not injected. Accordingly, as illustrated, the electrons flowing from the emitter electrode 52 to the drift region 18 flow through in order of the emitter electrode 52, the trench contact conductive portion 202, the first emitter portion 81, the second emitter portion 82, the third emitter portion 83, the base region 14, the accumulation region 16, and the drift region 18. Thus, the second emitter portion 82 of the present example can function as a resistance portion and suppress the saturation current flowing through the MOS structure.

FIG. 5B illustrates an example of an OFF operation of the semiconductor device 100. A bold arrow indicates a flow of holes. Since the contact region 15 of the present example is in contact with the trench contact conductive portion 202 at the bottom surface of the trench contact portion 200, excessive holes in the drift region 18 are swept out to the emitter electrode 52 via the trench contact conductive portion 202.

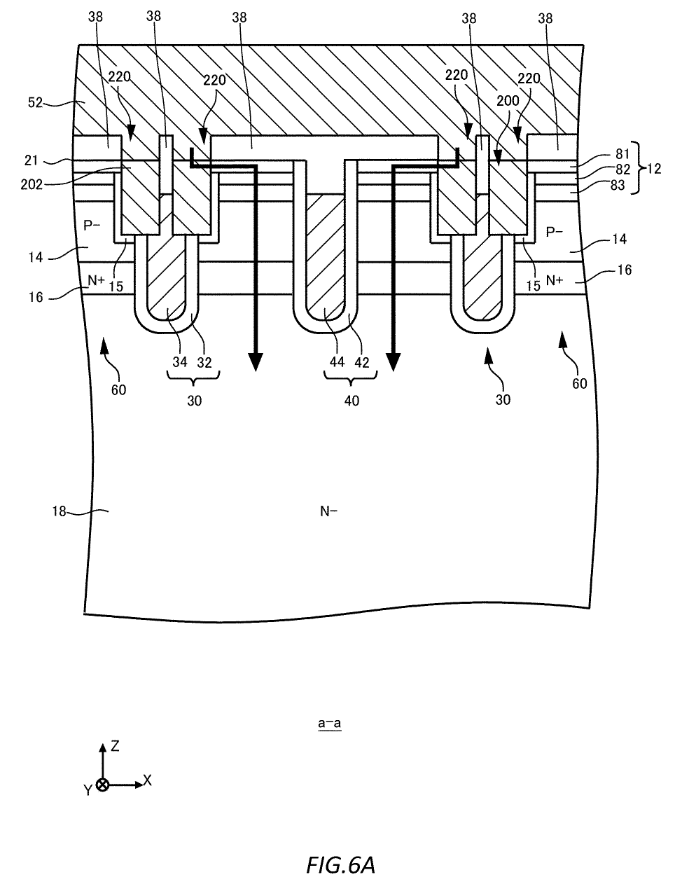

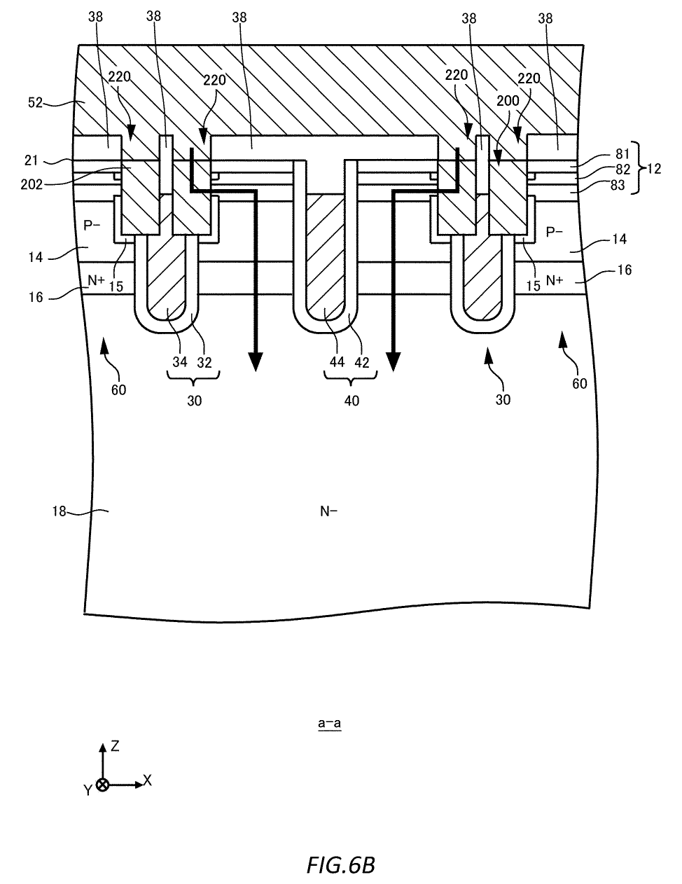

FIG. 6A illustrates an example of an ON operation of a semiconductor device according to a comparative example. In the semiconductor device according to the comparative example, the trench contact dielectric film 204 is not provided. FIG. 6A illustrates a case where the contact region 15 which is in contact with the bottom surface and the side surface of the trench contact portion 200 is provided as designed. At the bottom surface and the side surface of the trench contact portion 200, since a portion in which the trench contact conductive portion 202 and the contact region 15 are in contact with each other is reverse-biased, the electrons are not injected. Accordingly, as illustrated, the electrons flowing from the emitter electrode 52 to the drift region 18 flow through in order of the emitter electrode 52, the trench contact conductive portion 202, the first emitter portion 81, the second emitter portion 82, the third emitter portion 83, the base region 14, the accumulation region 16, and the drift region 18. Thus, the second emitter portion 82 according to the comparative example can function as a resistance portion and suppress the saturation current flowing through the MOS structure.

FIG. 6B illustrates another example of an ON operation of a semiconductor device according to the comparative example. FIG. 6B illustrates a case where the contact region 15 which is in contact with the bottom surface and the side surface of the trench contact portion 200 is not provided as designed, resulting in a deficiency. For example, when the contact region 15 is to be provided on the side surface of the trench contact portion 200, a process such as tilted ion implantation is required. In the ion implantation process, an obstruction such as a foreign substance may easily cause a deficiency.

When the contact region 15 has a deficiency, the trench contact conductive portion 202 and the third emitter portion 83 are in contact with each other in a portion of the contact region 15 with the deficiency, so that electrons are injected from the portion with the deficiency. That is, some electrons are injected into the drift region 18 without passing through the second emitter portion 82. Thus, the second emitter portion 82 may not function as a resistance portion and may not be able to suppress the saturation current flowing through the MOS structure.

In the semiconductor device according to the comparative example, high-concentration ions may be implanted or the contact region 15 may be diffused over a wider area in order to prevent the deficiency in the contact region 15. In this case, since an effective region of the second emitter portion 82 becomes smaller, it is required to widen the mesa portion 60 to achieve a desired characteristic, which may prevent miniaturization of the semiconductor device.

In the semiconductor device 100 according to the example, since the trench contact dielectric film 204 is provided between the trench contact conductive portion 202 and the third emitter portion 83, even when the contact region 15 has a deficiency, the electrons flowing from the emitter electrode 52 to the drift region 18 can pass through the second emitter portion 82. Thus, the second emitter portion 82 according to the example can function as a resistance portion and suppress the saturation current flowing through the MOS structure. In addition, in the semiconductor device 100 according to the example, since the desired characteristic can be achieved even when the contact region 15 has a deficiency, a yield can be improved.

In addition, since the semiconductor device 100 according to the example can achieve the desired characteristic even when the contact region 15 has a deficiency, it is not necessary to implant high-concentration ions or diffuse the contact region 15 over a wider area. Thus, it is not required to widen the mesa portion 60, and the semiconductor device 100 can be miniaturized.

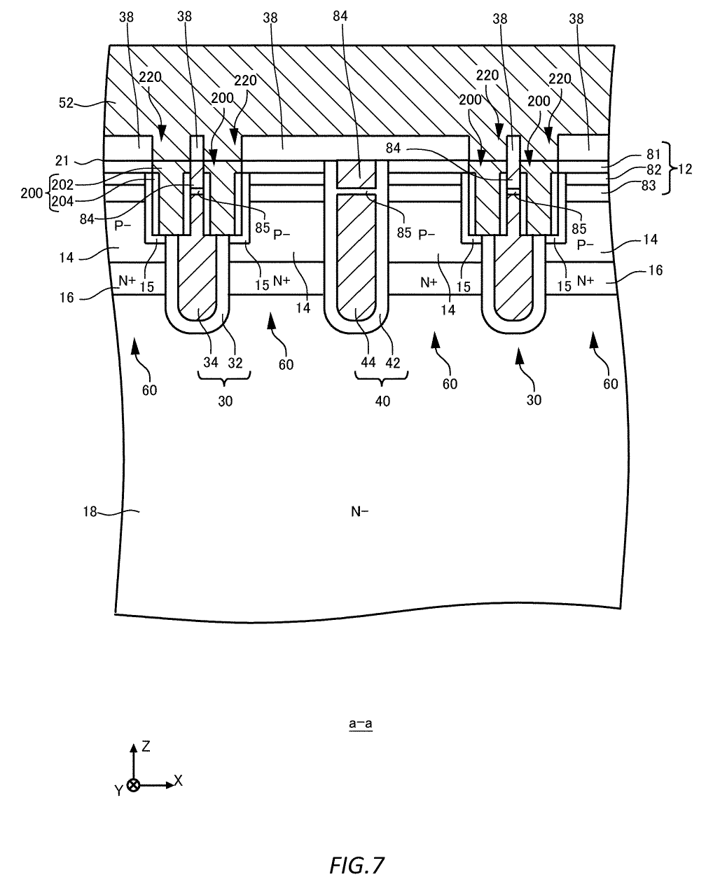

FIG. 7 illustrates another example of the cross section taken along the line a-a in FIG. 2. The semiconductor device 100 of the present example is different from that of the example of FIG. 3 in that a dummy conductive portion 84 is provided in a trench of the gate trench portion 40. In the present example, a difference from the example of FIG. 3 will be particularly described, and other configurations may be the same as those in the example of FIG. 3.

The gate trench portion 40 includes, in its trench, the dummy conductive portion 84 at an emitter potential, provided above the gate conductive portion 44. The dummy conductive portion 84 of the present example is provided between the front surface 21 of the semiconductor substrate 10 and the gate conductive portion 44. The dummy conductive portion 84 of the present example is covered with the gate dielectric film 42 on its side surfaces and insulated from the semiconductor substrate 10. An intermediate dielectric film 85 is provided between a lower end of the dummy conductive portion 84 of the present example and the gate conductive portion 44, and the dummy conductive portion 84 is insulated from the gate conductive portion 44. The intermediate dielectric film 85 may be formed of a same material as the gate dielectric film 42. A thickness of the intermediate dielectric film 85 may be 0.05 μm or more and 0.2 μm or less.

In the depth direction of the semiconductor substrate 10, the lower end of the dummy conductive portion 84 is arranged in a position which faces the third emitter portion 83. That is, the dummy conductive portion 84 of the present example is arranged in a position which faces the second emitter portion 82 provided above the third emitter portion 83.

In the semiconductor device 100 of the present example, the dummy conductive portion 84 of the gate trench portion 40 is arranged in the position which faces the second emitter portion 82, which can prevent the electrons from being attracted to the second emitter portion 82 due to an effect of the gate conductive portion 44 when the ON voltage is applied to the gate conductive portion 44.

Similar to the gate conductive portion 44, the dummy conductive portion 84 of the present example is formed of polysilicon, which is a conductive material. An upper end of the dummy conductive portion 84 of the present example is covered with the interlayer dielectric film 38. In another example, the dummy conductive portion 84 may be formed of a same material as the emitter electrode 52.

The dummy trench portion 30 may also include a dummy conductive portion 84 provided above the dummy conductive portion 34 and an intermediate dielectric film 85 provided at a lower end of the dummy conductive portion 84. Thus, the gate trench portion 40 and the dummy trench portion 30 can be formed in a same process. In another example, the dummy trench portion 30 may not include the dummy conductive portion 84, and the interlayer dielectric film 38 may be provided above the dummy conductive portion 34.

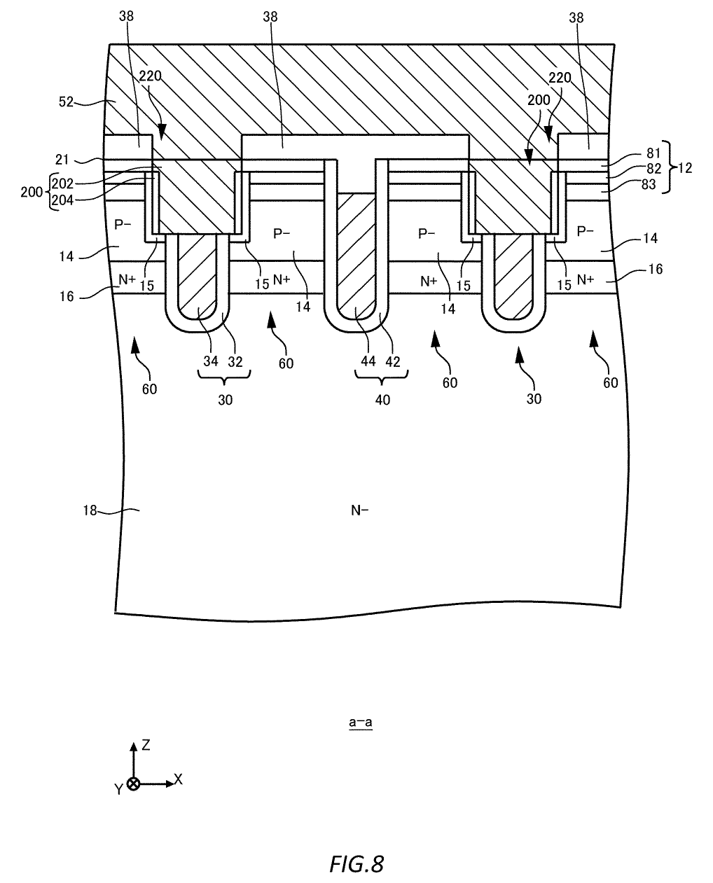

FIG. 8 illustrates another example of the cross section taken along the line a-a in FIG. 2. The semiconductor device 100 of the present example is different from the example of FIG. 3 in that a shape of the trench contact portion 200 is different. In the present example, a difference from the example of FIG. 3 will be particularly described, and other configurations may be the same as those in the example of FIG. 3.

The trench contact portion 200 may cover the dummy trench portion 30 from one end to another end of the dummy trench portion 30, in the arrangement direction of the dummy trench portion 30 and the gate trench portion 40, which is in the X axis direction in the present example. In the X axis direction, a width of the trench contact portion 200 may be greater than a width of the dummy trench portion 30.

Such structure facilitates filling a material of the trench contact conductive portion 202. Thus, the trench contact portion 200 can be easily provided, even when the mesa portion 60 is miniaturized.

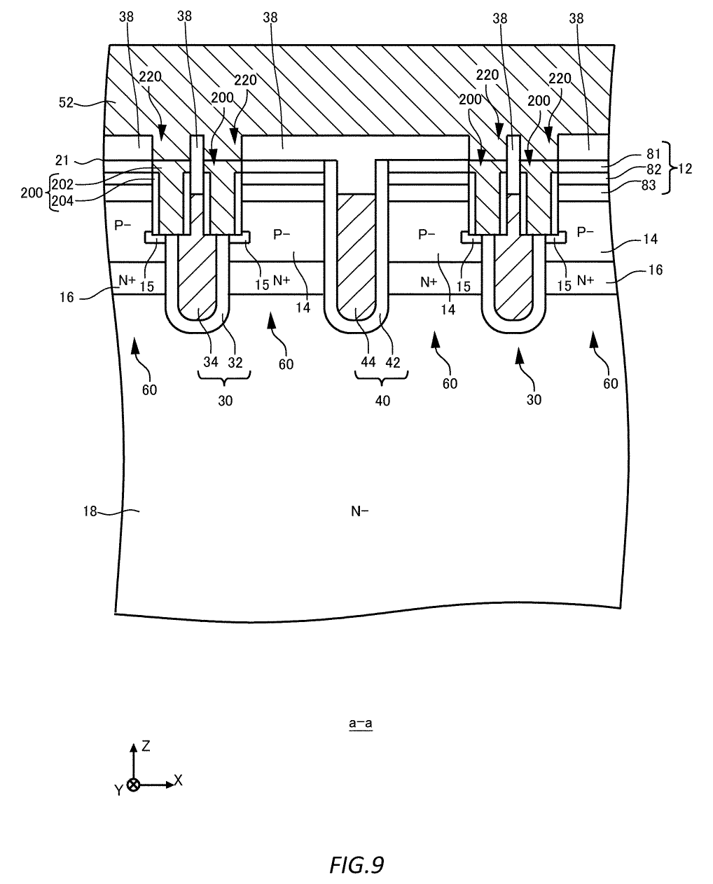

FIG. 9 illustrates another example of the cross section taken along the line a-a in FIG. 2. The semiconductor device 100 of the present example is different from the example of FIG. 3 in that the contact region 15 is provided in a different area. In the present example, a difference from the example of FIG. 3 will be particularly described, and other configurations may be the same as those in the example of FIG. 3.

The contact region 15 may be in contact with the bottom surface of the trench contact portion 200. The contact region 15 may be in contact with the trench contact conductive portion 202 on the bottom surface of the trench contact portion 200. Thus, excessive holes in the drift region 18 are swept out to the emitter electrode 52 via the trench contact conductive portion 202. Note that the contact region 15 may also be provided partially on the side surfaces of the trench contact portion 200.

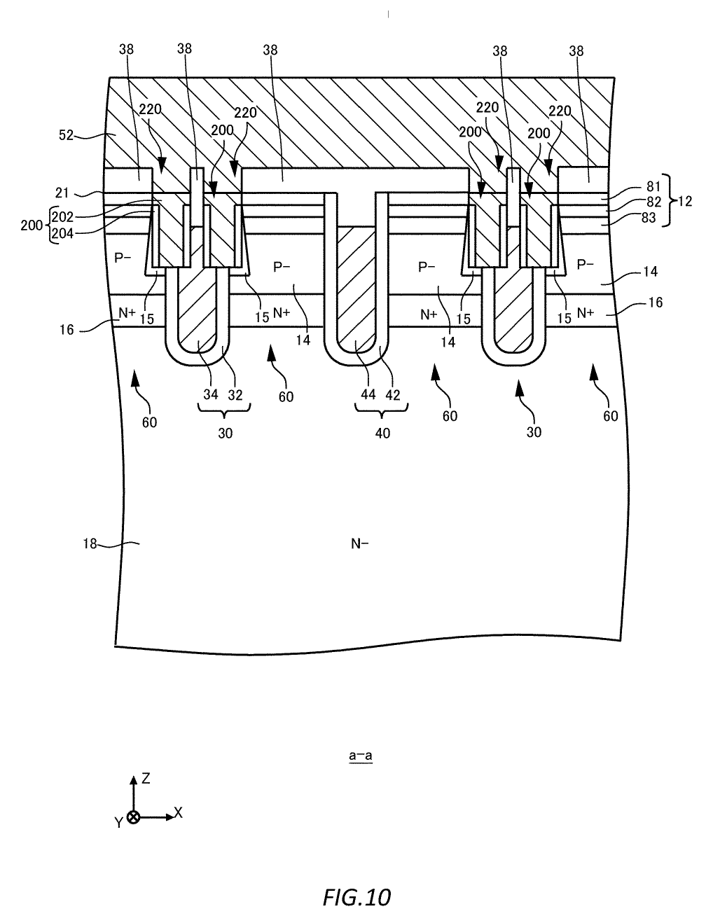

FIG. 10 illustrates another example of the cross section taken along the line a-a in FIG. 2. The semiconductor device 100 of the present example is different from the example of FIG. 3 in that the contact region 15 is provided in a different area. In the present example, a difference from the example of FIG. 3 will be particularly described, and other configurations may be the same as those in the example of FIG. 3.

The contact region 15 may be in contact with the bottom surface and the side surface of the trench contact portion 200. The contact region 15 may be provided between the trench contact conductive portion 202 and the third emitter portion 83. The contact region 15 may have a distribution of width of the semiconductor substrate 10 in the horizontal direction (the X axis direction in the present example), in the depth direction of the semiconductor substrate 10. That is, a width of the contact region 15 may not be uniform in the depth direction of the semiconductor substrate 10.

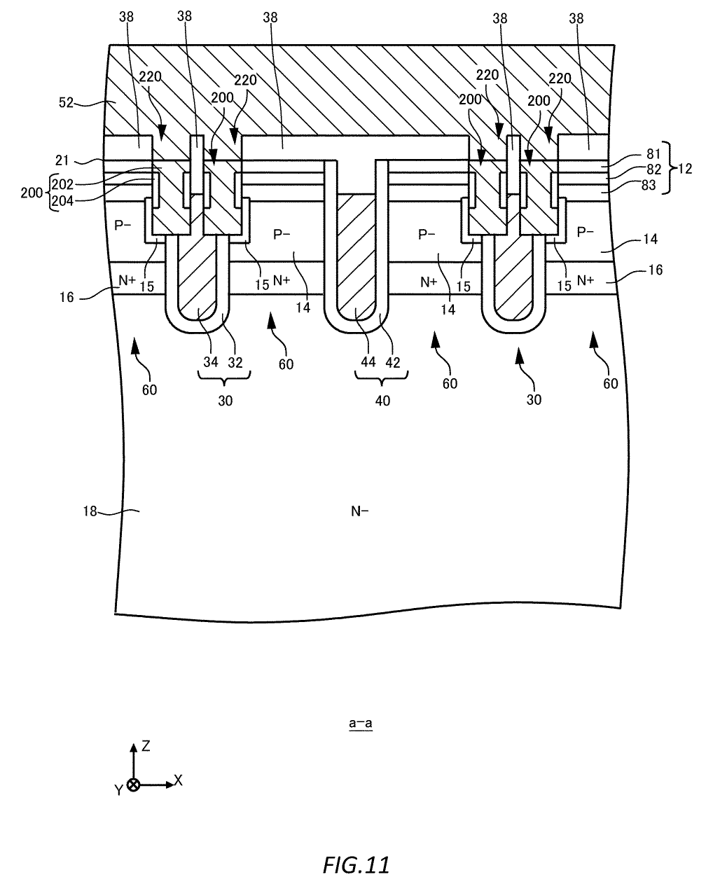

FIG. 11 illustrates another example of the cross section taken along the line a-a in FIG. 2. The semiconductor device 100 of the present example is different from the example of FIG. 3 in that the trench contact dielectric film 204 is provided in a different area. In the present example, a difference from the example of FIG. 3 will be particularly described, and other configurations may be the same as those in the example of FIG. 3.

The trench contact dielectric film 204 may be spaced apart from the lower end of the trench contact portion 200. Thus, a contact area between the contact region 15 and the trench contact conductive portion 202 at a bottom portion of the trench contact portion 200 increases, thereby allowing the excessive holes in the drift region 18 to be swept out more reliably to the emitter electrode 52 via the trench contact conductive portion 202. The side surface of the trench contact portion 200 which faces the third emitter portion 83 may be in contact with at least one of the trench contact dielectric film 204 or the contact region 15.

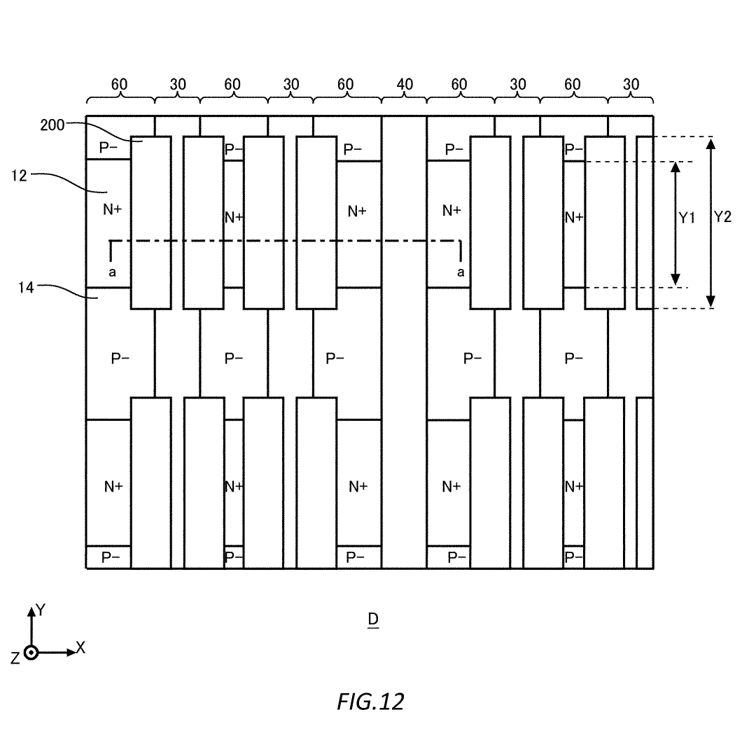

FIG. 12 is another example of the enlarged view of the region D in FIG. 1. The semiconductor device 100 of the present example is different from that in the example of FIG. 2, in that two dummy trench portions 30 are arranged between two gate trench portions 40 in the X axis direction. Another configuration may be the same as that of the example of FIG. 2. Note that three or more dummy trench portions 30 may be arranged between two gate trench portions 40 in the X axis direction.

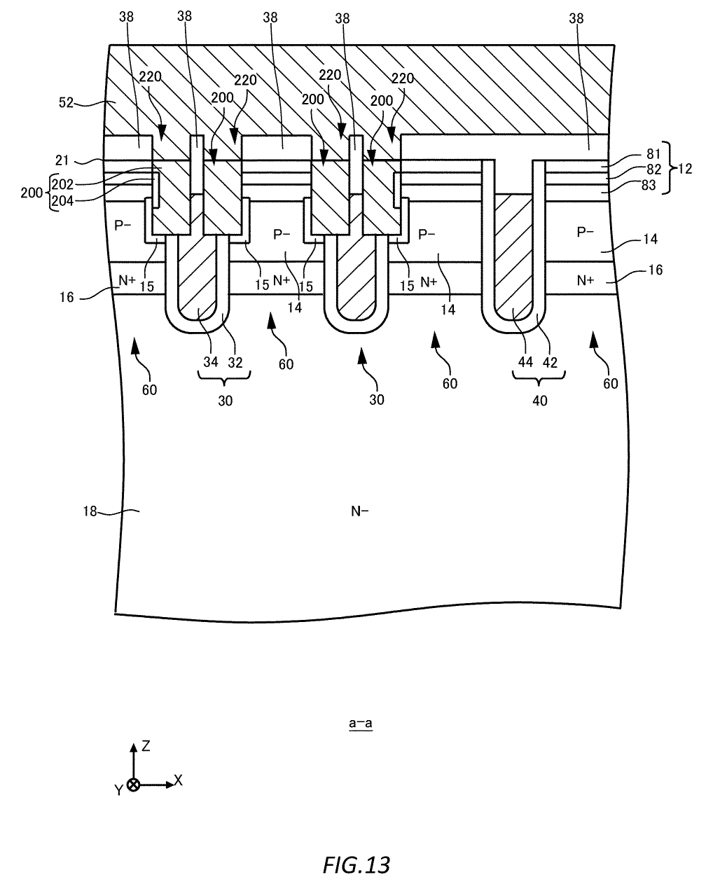

FIG. 13 illustrates an example of a cross section taken along a line a-a in FIG. 12. The semiconductor device 100 of the present example is different from the example of FIG. 3 in that the trench contact dielectric film 204 is provided in a different position. In the present example, a difference from the example of FIG. 3 will be particularly described, and other configurations may be the same as those in the example of FIG. 3.

The trench contact dielectric film 204 may be provided on a side surface of the side surfaces of the trench contact portion 200 which faces the gate trench portion 40. The trench contact dielectric film 204 may not be provided on a side surface of the side surfaces of the trench contact portion 200 which faces the dummy trench portion 30. In addition, the trench contact dielectric film 204 may not be provided on a side surface with which the trench contact portions 200 face each other.

As described above, when a predetermined ON voltage is applied to the gate trench portion 40, a surface layer of the base region 14 in contact with the gate trench portion 40 is inverted to the N type region to form a channel, and the emitter region 12 and the drift region 18 are electrically connected. Since such ON voltage is not applied to the dummy trench portion 30, a surface layer of the base region 14 is not inverted to the N type region, and the emitter region 12 and the drift region 18 are not electrically connected. That is, electrons do not flow through the mesa portion 60 which is sandwiched by the dummy trench portions 30 on both sides. Thus, even when the trench contact dielectric film 204 is not provided on a side surface of the side surfaces of the trench contact portion 200 which faces the dummy trench portion 30, it does not affect its characteristic to suppress the saturation current.

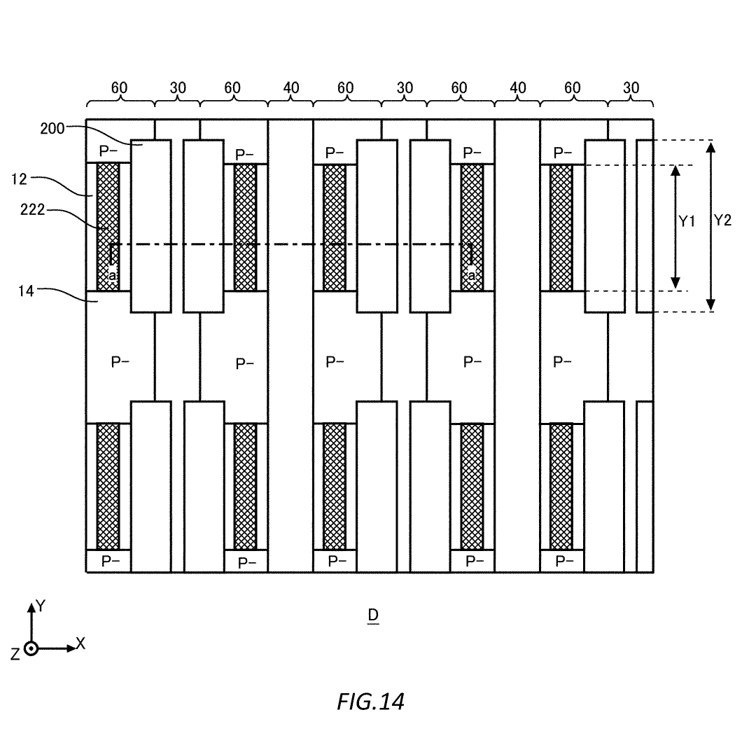

FIG. 14 is another example of the enlarged view of the region D in FIG. 1. The semiconductor device 100 of the present example is different from the example of FIG. 2 in that contact holes 222 are provided in the interlayer dielectric film 38 above the emitter region 12. Another configuration may be the same as that of the example of FIG. 2.

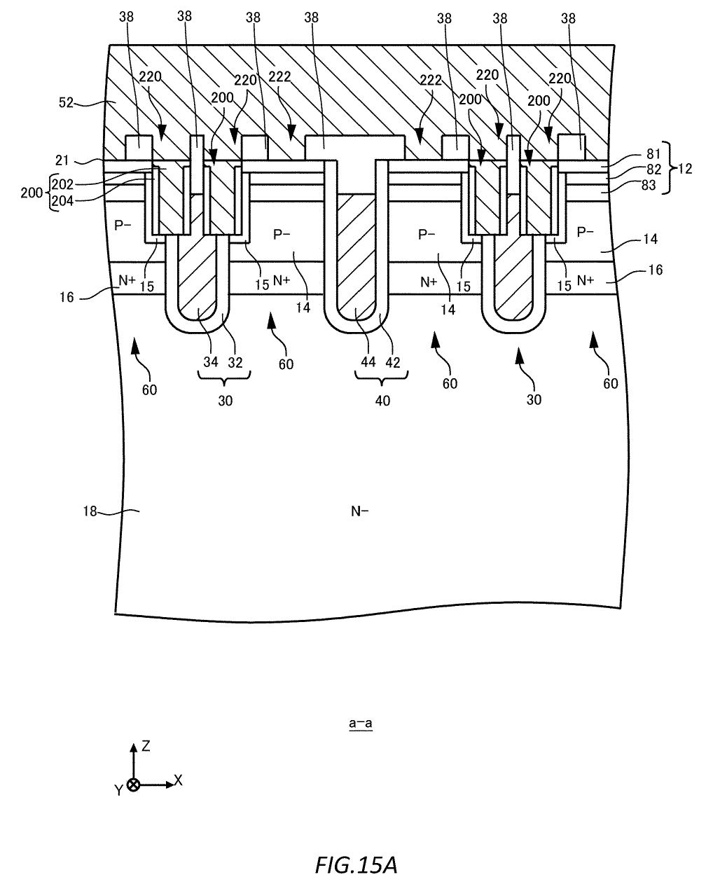

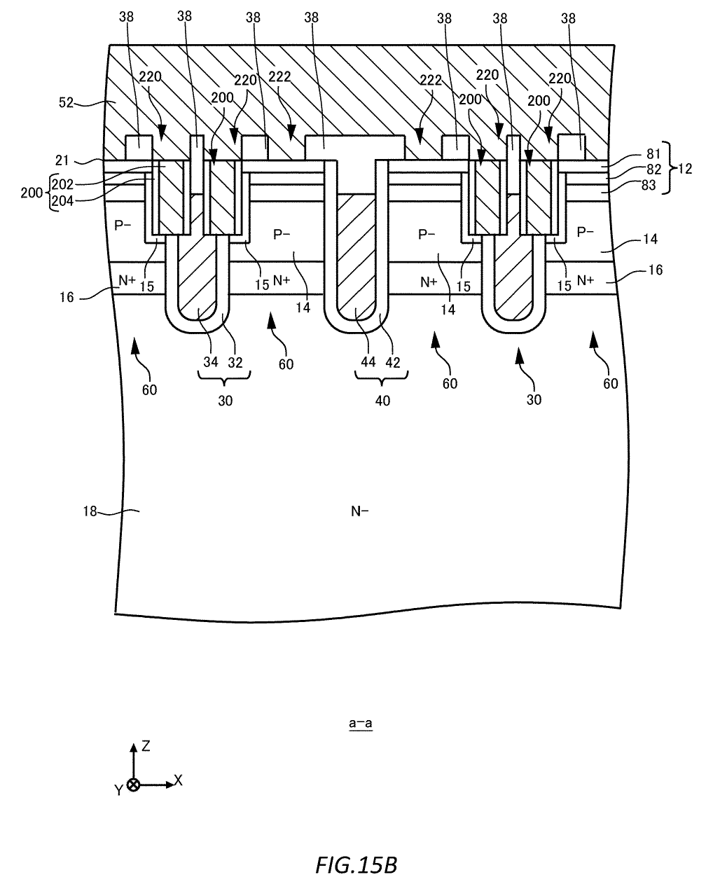

FIG. 15A illustrates an example of a cross section taken along a line a-a in FIG. 14. The semiconductor device 100 of the present example is different from the example of FIG. 3 in that the contact holes 222 are provided in the interlayer dielectric film 38 above the emitter region 12 and the trench contact dielectric film 204 is provided in a different area. In the present example, a difference from the example of FIG. 3 will be particularly described, and other configurations may be the same as those in the example of FIG. 3.

The trench contact dielectric film 204 may be provided between the trench contact conductive portion 202 and the third emitter portion 83, between the trench contact conductive portion 202 and the second emitter portion 82, and at least partially between the trench contact conductive portion 202 and the first emitter portion 81. In this case, since a contact area between the first emitter portion 81 and the trench contact conductive portion 202 decreases, electrons may have difficulty flowing from the emitter electrode 52 to the drift region 18.

The first emitter portion 81 may be connected to the emitter electrode 52 via each contact hole 222. Thus, even when the contact area between the first emitter portion 81 and the trench contact conductive portion 202 decreases, electrons can flow from the emitter electrode 52 to the drift region 18. Note that, even in a case where the trench contact dielectric film 204 is not provided between the trench contact conductive portion 202 and the first emitter portion 81, as in the example of FIG. 3 or the like, the contact holes 222 may still be provided, not just in a case where the trench contact dielectric film 204 is provided at least partially between the trench contact conductive portion 202 and the first emitter portion 81.

FIG. 15B illustrates another example of the cross section taken along the line a-a in FIG. 14. The semiconductor device 100 of the present example is different from that in the example of FIG. 15A in that the trench contact dielectric film 204 is provided to an upper end of the trench contact portion 200. Also in this case, since the first emitter portion 81 is connected to the emitter electrode 52 via the contact hole 222, electrons can flow from the emitter electrode 52 to the drift region 18.

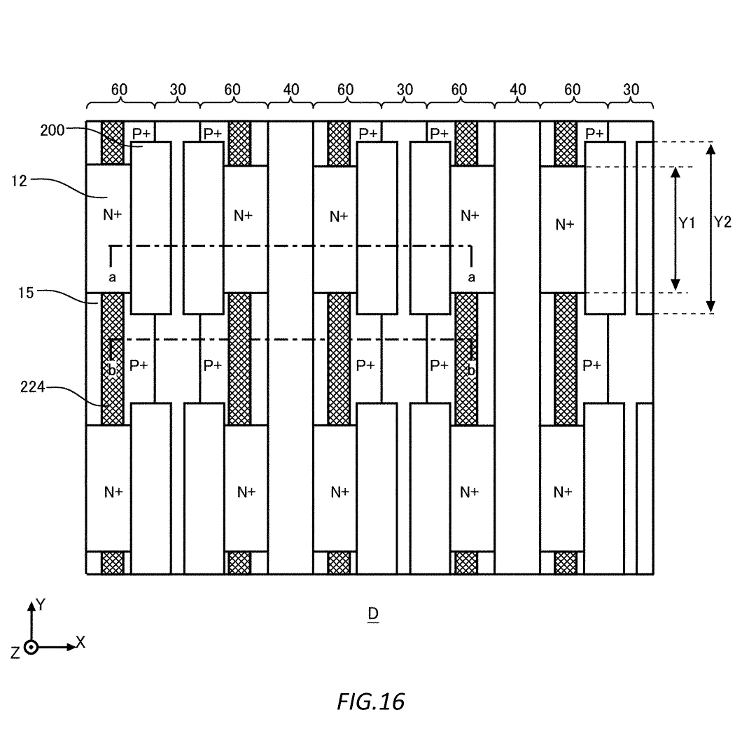

FIG. 16 is another example of the enlarged view of the region D in FIG. 1. The semiconductor device 100 of the present example is different from that in the example of FIG. 2 in that the contact region 15 is exposed at the front surface 21 of the semiconductor substrate 10. In the present example, the emitter region 12 and the contact region 15 are arranged alternately in the mesa portion 60, in a top view of the semiconductor substrate 10. Contact holes 224 may be provided in the interlayer dielectric film 38 above the contact region 15. Another configuration may be the same as that of the example of FIG. 2. In addition, a cross-sectional view taken along a line a-a in FIG. 16 may correspond to any of aspects described in FIG. 3, FIG. 7 through FIG. 11, FIG. 13, FIG. 15A, and FIG. 15B.

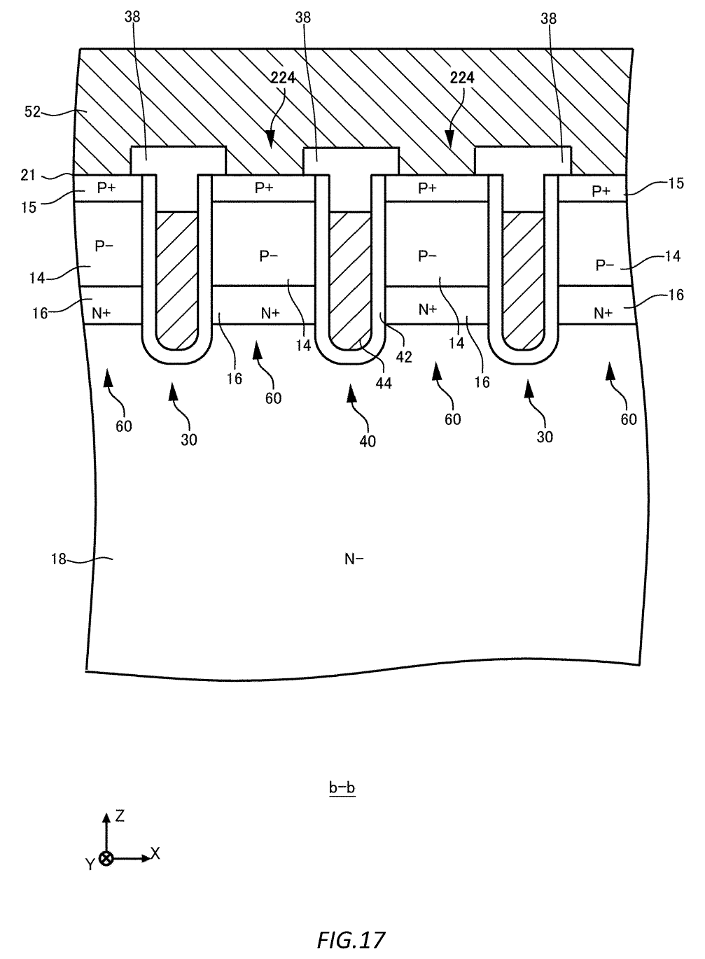

FIG. 17 illustrates an example of a cross section taken along a line b-b in FIG. 16. The cross section taken along the line b-b in FIG. 16 is an XZ cross section passing through the contact region 15. The contact region 15 of the present example is provided on the front surface 21 of the semiconductor substrate 10. The contact region 15 is connected to the emitter electrode 52 via each contact hole 224. Thus, excessive holes in the drift region 18 are swept out to the emitter electrode 52.

While the present invention has been described by way of the embodiments, the technical scope of the present invention is not limited to the above-described embodiments. It is apparent to persons skilled in the art that various alterations or improvements can be made to the above described embodiments. It is also apparent from description of the claims that the embodiments to which such modifications or improvements are made may be included in the technical scope of the present invention.

It should be noted that each process of the operations, procedures, steps, steps, and the like performed by the apparatus, system, program, and method shown in the claims, specification, or drawings can be executed in any order as long as the order is not indicated by “prior to”, “before”, or the like and as long as the output from a previous process is not used in a later process. Even if the operation flow is described using phrases such as "first" or "next" for the sake of convenience in the claims, specification, or drawings, it does not necessarily mean that the process must be performed in this order.

### EXPLANATION OF REFERENCES

10: semiconductor substrate; 11: P type outer circumferential well region; 12: emitter region; 14: base region; 15: contact region; 16: accumulation region; 18: drift region; 20: buffer region; 21: front surface; 22: collector region; 23: back surface; 24: collector electrode; 30: dummy trench portion; 32: dummy dielectric film; 34: dummy conductive portion; 38: interlayer dielectric film; 40: gate trench portion; 42: gate dielectric film; 44: gate conductive portion; 52: emitter electrode; 60: mesa portion; 70: transistor portion; 81: first emitter portion; 82: second emitter portion; 83: third emitter portion; 84: dummy conductive portion; 85: intermediate dielectric film; 90: edge termination structure portion; 100: semiconductor device; 130: gate wiring line; 160: active portion; 161: first end side; 162: second end side; 164: gate pad; 200: trench contact portion; 202: trench contact conductive portion; 204: trench contact dielectric film; 220: contact hole; 222: contact hole; 224: contact hole.

What is claimed is:

1. A semiconductor device comprising:
a drift region of a first conductivity type which is provided in a semiconductor substrate;
a gate trench portion provided on a front surface of the semiconductor substrate;
a base region of a second conductivity type which is provided above the drift region;
an emitter region of the first conductivity type which is provided above the base region and has a doping concentration which is higher than the drift region; and
a trench contact portion which is provided from the front surface of the semiconductor substrate to a position deeper than an upper end of the base region, wherein
the emitter region comprises
a first emitter portion which is in contact with the front surface of the semiconductor substrate;
a second emitter portion which is provided below the first emitter portion and has a doping concentration which is lower than the first emitter portion; and
a third emitter portion which is provided below the second emitter portion and has a doping concentration which is higher than the second emitter portion, and
the trench contact portion comprises
a trench contact conductive portion; and
a trench contact dielectric film provided at least partially on a side surface of the trench contact portion, and
the trench contact dielectric film is provided between the trench contact conductive portion and the third emitter portion.

2. The semiconductor device according to claim 1, wherein
the first emitter portion is in contact with the trench contact conductive portion, and
the third emitter portion is spaced apart from the trench contact conductive portion.

3. The semiconductor device according to claim 1, wherein
the trench contact dielectric film is provided between the trench contact conductive portion and the third emitter portion, and between the trench contact conductive portion and the second emitter portion.

4. The semiconductor device according to claim 3, wherein
the first emitter portion is in contact with the trench contact conductive portion, and
the second emitter portion and the third emitter portion are spaced apart from the trench contact conductive portion.

5. The semiconductor device according to claim 1, wherein
the doping concentration of the third emitter portion is lower than a maximum doping concentration of the first emitter portion.

6. The semiconductor device according to claim 1, wherein
the trench contact dielectric film is in contact with a lower end of the trench contact portion.

7. The semiconductor device according to claim 1, wherein
the trench contact dielectric film is spaced apart from a lower end of the trench contact portion.

8. The semiconductor device according to claim 1, comprising:
a contact region of the second conductivity type which is provided above the drift region and has a doping concentration which is higher than the base region, wherein
the contact region is in contact with a bottom surface of the trench contact portion.

9. The semiconductor device according to claim 8, wherein
the contact region is in contact with the trench contact conductive portion on the bottom surface of the trench contact portion.

10. The semiconductor device according to claim 8, wherein
the contact region is
in contact with the bottom surface and the side surface of the trench contact portion, and
provided between the trench contact conductive portion and the third emitter portion.

11. The semiconductor device according to claim 1, comprising:
a dummy trench portion which comprises a dummy conductive portion and a dummy dielectric film, wherein
the trench contact portion is provided above the dummy trench portion.

12. The semiconductor device according to claim 11, wherein
the trench contact portion covers the dummy trench portion from one end to another end of the dummy trench portion, in an arrangement direction of the dummy trench portion and the gate trench portion.

13. The semiconductor device according to claim 11, wherein
the trench contact portion comprises a plurality of trench contact portions provided above the dummy trench portion.

14. The semiconductor device according to claim 11, wherein
the trench contact conductive portion is in contact with the dummy conductive portion.

15. The semiconductor device according to claim 11, wherein
the side surface includes a plurality of side surfaces, and
the trench contact dielectric film is provided on a side surface of the plurality of side surfaces of the trench contact portion which faces the gate trench portion.

16. The semiconductor device according to claim 15, wherein
the trench contact dielectric film is not provided on a side surface of the plurality of side surfaces of the trench contact portion which faces the dummy trench portion.

17. The semiconductor device according to claim 2, comprising:
a dummy trench portion which comprises a dummy conductive portion and a dummy dielectric film, wherein
the trench contact portion is provided above the dummy trench portion.

18. The semiconductor device according to claim 1, comprising:
an interlayer dielectric film which is provided above the semiconductor substrate and comprises a contact hole; and
an emitter electrode provided above the interlayer dielectric film, wherein
the first emitter portion is connected to the emitter electrode via the contact hole.

19. The semiconductor device according to claim 2, comprising:
an interlayer dielectric film which is provided above the semiconductor substrate and comprises a contact hole; and
an emitter electrode provided above the interlayer dielectric film, wherein
the first emitter portion is connected to the emitter electrode via the contact hole.

20. The semiconductor device according to claim 1, wherein
the semiconductor substrate is a silicon substrate or a wide bandgap semiconductor substrate.
